(19) United States
(12) Patent Application Publication
(10) Pub. No.: US 2025/0127004 A1
(43) Pub. Date: Apr. 17, 2025

(54) DISPLAY PANEL AND DISPLAY DEVICE

(71) Applicant: Wuhan Tianma Microelectronics Co., Ltd., Wuhan (CN)

(72) Inventors: Yu CAI, Wuhan (CN); Miao WANG, Wuhan (CN)

(73) Assignee: Wuhan Tianma Microelectronics Co., Ltd., Wuhan (CN)

(21) Appl. No.: 18/576,387

(22) PCT Filed: Sep. 28, 2022
(86) PCT No.: PCT/CN2022/122022

§ 371 Date: Jan. 4, 2024

(30) Foreign Application Priority Data
Jun. 29, 2022 (CN) 202210750714.9

(51) Int. Cl. H10K 59/35; H10K 50/13

(52) U.S. Cl. CPC H10K 59/353; H10K 59/351; H10K 50/13

(57) ABSTRACT

Provided are a display panel and a display device. The display panel includes a first display region, a second display region, a substrate, first light-emitting units and second light-emitting units. The first light-emitting units are disposed on one side of the substrate in the first display region. A first light-emitting unit includes m light-emitting layers, m is an integer greater than or equal to 2, and the m light-emitting layers include a first light-emitting layer and a second light-emitting layer. The orthographic projection of the first light-emitting layer on the substrate at least partially overlaps the orthographic projection of the second light-emitting layer on the substrate. The second light-emitting units are disposed on one side of the substrate in the second display region. A second light-emitting unit includes n light-emitting layers, and n is an integer greater than or equal to 1.

### CROSS-REFERENCES TO RELATED APPLICATIONS

This application claims priority to Chinese Patent Application No. 202210750714.9 filled on Jun. 29, 2022 and entitled “DISPLAY PANEL AND DISPLAY DEVICE”, the disclosure of which is incorporated herein by reference in its entirety.

### TECHNICAL FIELD

The present application relates to the field of display technologies and, in particular, to a display panel and a display device.

### BACKGROUND

With the development of science and technology, organic light-emitting display devices become more and more popular and widely used. The organic light-emitting display devices have the advantages of self-luminescence, a wide viewing angle, high contrast and a short response time and thereby have a good prospect.

However, in an organic display device, structures in different regions are not the same, so it is prone to a deviation in light-emitting effect and a problem of non-uniform brightness may occur.

### SUMMARY

Embodiments of the present application provide a display panel and a display device so that the display uniformity of different regions can be improved.

In a first aspect, embodiments of the present application provide a display panel. The display panel includes a first display region, a second display region, a substrate, first light-emitting units and second light-emitting units. The first light-emitting units are disposed on one side of the substrate in the first display region. A first light-emitting unit includes m light-emitting layers, m is an integer greater than or equal to 2, and the m light-emitting units include a first light-emitting layer and a second light-emitting layer. An orthographic projection of the first light-emitting layer on the substrate at least partially overlaps an orthographic projection of the second light-emitting layer on the substrate.

The second light-emitting units are disposed on one side of the substrate in the second display region. A second light-emitting unit includes n light-emitting layers, and n is an integer greater than or equal to 1. An effective light-emitting area of the first light-emitting unit is different from an effective light-emitting area of the second light-emitting unit. The effective light-emitting area is an orthographic projection area of the first light-emitting unit on the substrate or an orthographic projection area of the second light-emitting unit on the substrate, or the effective light-emitting area is a sum of orthographic projection areas of the m light-emitting layers in the first light-emitting unit on the substrate or a sum of orthographic projection areas of the n light-emitting layers in the second light-emitting unit on the substrate.

In a second aspect, embodiments of the present application provide a display device. The display device includes the display panel in any preceding embodiment.

In the display panel and the display device provided in the embodiments of the present application, the first light-emitting units are disposed in the first display region, the second light-emitting units are disposed in the second display region, and the effective light-emitting area of the first light-emitting unit is different from the effective light-emitting area of the second light-emitting unit so that the brightness of the first display region and the second display region can be adjusted, thereby improving the brightness uniformity of different regions and improving the display effect.

### BRIEF DESCRIPTION OF DRAWINGS

To illustrate schemes in embodiments of the present application more clearly, the drawings used in description of the embodiments of the present application will be briefly described below. Apparently, the drawings described below illustrate part of embodiments of the present application, and those of ordinary skill in the art may obtain other drawings based on the drawings described below on the premise that no creative work is done.

FIG. 1 is a diagram illustrating the structure of a display panel according to an embodiment of the present application.

FIG. 2 is an enlarged diagram illustrating the structure of region Q in FIG. 1.

FIG. 3 is a sectional diagram illustrating the structure of A-A in FIG. 2.

FIG. 4 is an enlarged diagram illustrating the structure of a first light-emitting unit in FIG. 3.

FIG. 5 is an enlarged diagram illustrating the structure of region P in FIG. 1.

FIG. 6 is a sectional diagram illustrating the structure of B-B in FIG. 5.

FIG. 7 is an enlarged diagram illustrating the structure of a second light-emitting unit in FIG. 6.

FIG. 8 is a top view illustrating the structure of a first light-emitting unit in a display panel according to an embodiment of the present application.

FIG. 9 is a diagram illustrating a cross-sectional structure of C-C in FIG. 8.

FIG. 10 is a diagram illustrating a cross-sectional structure of B-B in another display panel according to an embodiment of the present application.

FIG. 11 is a simplified diagram illustrating the structure shown in FIG. 10.

FIG. 12 is a sectional diagram illustrating the structure of a second light-emitting unit in another display panel according to an embodiment of the present application.

FIG. 13 is a simplified diagram illustrating the structure of a second light-emitting unit and a third light-emitting unit in another display panel according to an embodiment of the present application.

FIG. 14 is an enlarged diagram illustrating the structure of region Q in another display region according to an embodiment of the present application.

FIG. 15 is an enlarged diagram illustrating the structure of region P in another display region according to an embodiment of the present application.

FIG. 16 is a diagram illustrating a cross-sectional structure of D-D in FIG. 14.

FIG. 17 is a diagram illustrating the structure of a display device according to an embodiment of the present application.

### REFERENCE LIST

1 substrate
2 first light-emitting unit
21 first light-emitting layer
22 second light-emitting layer
23 fifth light-emitting layer
24 first connecting layer
241 first doping layer
242 second doping layer
3 second light-emitting unit
31 third light-emitting layer
32 fourth light-emitting layer
33 second connecting layer
331 third doping layer
332 fourth doping layer
333 through hole
34 seventh light-emitting layer
4 driver chip
5 pixel defining layer
51 first opening
52 second opening
6 third light-emitting unit
61 sixth light-emitting layer
71 first barrier column
72 second barrier column
8 array layer
91 cathode
92 anode
93 hole transport layer
AA display region
A1 first display region
A2 second display region
NA non-display region
X thickness direction

### DETAILED DESCRIPTION

Features of various aspects and exemplary embodiments of the present application are described below in detail. Objects, technical solutions and advantages of the present application will be clearer from a detailed description of the present application in conjunction with the drawings and embodiments. It is to be understood that the embodiments described herein are merely intended to explain the present application and not to limit the present application. For those skilled in the art, the present application may be implemented without some of these specific details. The following description of the embodiments is merely intended to provide a better understanding of the present application by way of examples of the present application.

It is to be noted that in the description, relationship terms such as “first” and “second” are merely used for distinguishing one entity or operation from another and do not necessarily require or imply any such actual relationship or order between these entities or operations. Moreover, the term “comprising”, “including” or any other variant thereof is intended to encompass a non-exclusive inclusion so that a process, method, article, or device that includes a series of elements not only includes those elements but also includes other elements that are not expressly listed or are inherent to such process, method, article, or device. In the absence of more restrictions, the elements defined by the statement “including . . . ” do not exclude the presence of additional identical elements in the process, method, article or device that includes the elements.

Multiple function films are included in a display panel. Exemplarily, the display panel includes an array substrate, a light-emitting component layer, an encapsulation layer and others. A driving circuit is included in the array substrate. Light-emitting units are included in the light-emitting component layer. The driving circuit is electrically connected to the light-emitting units and controls the light-emitting intensity of the light-emitting units.

Structures of different regions in the display panel are not the same. Exemplarily, the arrangement modes of light-emitting units or the structures of single light-emitting units in the different regions of the display panel may be different, resulting in different transmittances of different regions. Alternatively, the wiring modes of driving circuits in different regions of the display panel may be different to fulfill different driving functions. Different structures of the different regions in the display panel are prone to different light-emitting brightness of the different regions, thereby affecting normal impressions of human eyes.

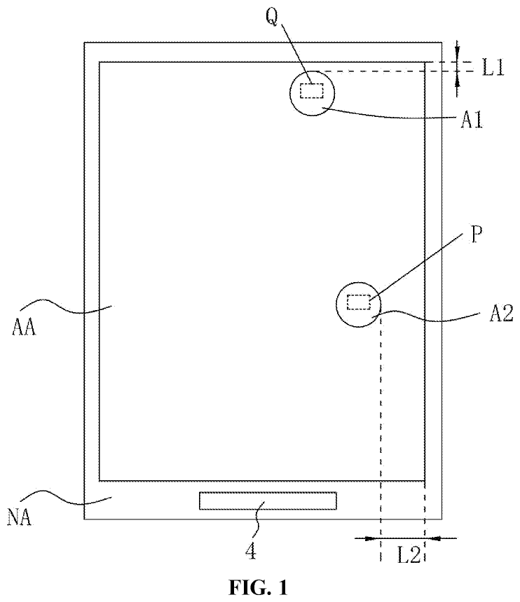

To solve the preceding problem, referring to FIGS. 1 to 7, an embodiment of the present application provides a display panel. The display panel includes a first display region A1, a second display region A2, a substrate 1, first light-emitting units 2 and second light-emitting units 3. The first light-emitting units 2 are disposed on one side of the substrate 1 in the first display region A1. A first light-emitting unit 2 includes m light-emitting layers, m is an integer greater than or equal to 2, and the m light-emitting units include a first light-emitting layer 21 and a second light-emitting layer 22. The orthographic projection of the first light-emitting layer 21 on the substrate 1 at least partially overlaps the orthographic projection of the second light-emitting layer 22 on the substrate 1.

The second light-emitting units 3 are disposed on one side of the substrate 1 in the second display region A2. A second light-emitting unit 3 includes n light-emitting layers, and n is an integer greater than or equal to 1. The effective light-emitting area of the first light-emitting unit 2 is different from the effective light-emitting area of the second light-emitting unit 3.

The display panel includes a display region AA and a non-display region NA around the peripheral side of the display region AA. The first display region A1 and the second display region A2 are located in the display region AA.

The substrate 1 may be a rigid substrate made of a material such as glass. Alternatively, the substrate 1 may be a flexible substrate made of a light-transmissive material such as polyimide (PI). The first light-emitting units 2 and the second light-emitting units 3 are located on the same side of the substrate 1 and are both configured to emit light. The first display region A1 cooperates with the second display region A2 to display so that a specific picture image can be displayed. Exemplarily, the first display region A1 includes not only the first light-emitting units 2 but also multiple kinds of light-emitting units having other emitted colors, and the emitted colors include but are not limited to, red, green and blue. The second display region A2 is in the same vein.

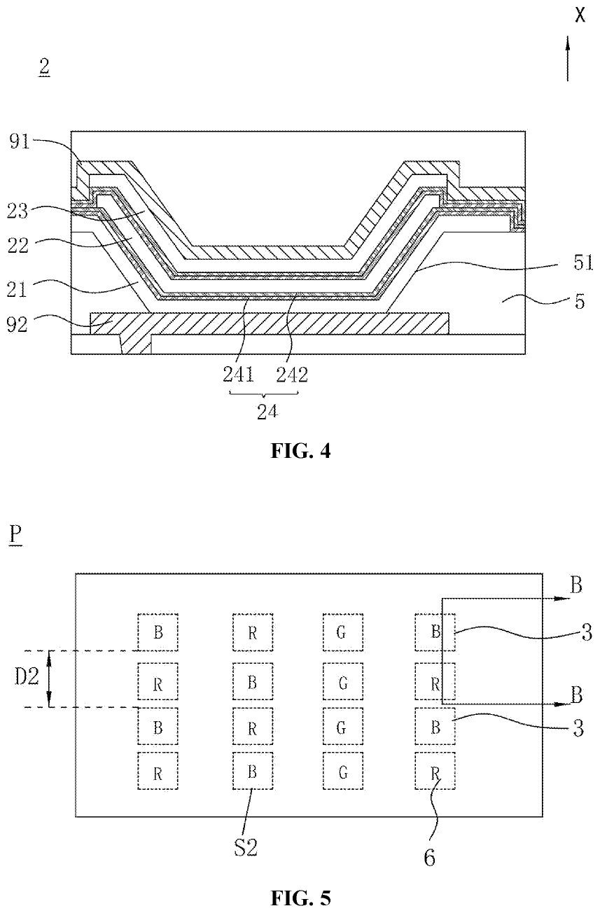

As shown in FIGS. 3 and 4, the first light-emitting unit 2 includes the m light-emitting layers, and m is an integer greater than or equal to 2, that is, light emitted by the first light-emitting unit 2 is a set of light emitted by the multiple light-emitting layers. The first light-emitting unit 2 further includes a hole transport layer (not shown in the figure) and an anode 92 on one side of the m light-emitting layers facing the substrate 1 as well as an electron transport layer (not shown in the figure) and a cathode 91 on the other side of the m light-emitting layers facing away from the substrate 1. A first connecting layer 24 is disposed between adjacent light-emitting layers and plays a role in connecting the adjacent light-emitting layers in series. Jointly driven by the cathode 91 and the anode 92, electrons and holes are respectively transmitted to the nearest light-emitting layers through an electron transport layer and a hole transport layer and then transmitted to light-emitting layers adjacent to the nearest light-emitting layers through the first connecting layer 24, and the multiple light-emitting layers emit light jointly so as to emit stronger light than that of a single light-emitting layer. This enables the first light-emitting unit 2 to be able to emit light having stronger brightness without enhancing a drive current.

The m light-emitting layers include the first light-emitting layer 21 and the second light-emitting layer 22. It is to be noted that “the orthographic projection of the first light-emitting layer 21 on the substrate 1 at least partially overlaps the orthographic projection of the second light-emitting layer 22 on the substrate 1” refers to that the first light-emitting layer 21 has a first orthographic projection on the substrate 1, the second light-emitting layer 22 has a second orthographic projection on the substrate 1, and an overlapping region is present between the first orthographic projection and the second orthographic projection.

When the first light-emitting unit 2 emits light, the first light-emitting layer 21 and the second light-emitting layer 22 emit light jointly, and stronger light is emitted at a position corresponding to the overlapping region, thereby improving the light-emitting brightness. Alternatively, the orthographic projection of the first light-emitting layer 21 on the substrate 1 coincides with the orthographic projection of the second light-emitting layer 22 on the substrate 1.

In addition, the m light-emitting layers in the first light-emitting unit 2 not only include the first light-emitting layer 21 and the second light-emitting layer 22 but may also include other light-emitting layers. Exemplarily, as shown in FIG. 4, the first light-emitting unit 2 further includes a fifth light-emitting layer 23.

It is to be noted that the m light-emitting layers in the first light-emitting unit 2 may have the same emitted color or different emitted colors. This is not limited in the embodiments of the present application. When at least part of the m light-emitting layers in the first light-emitting unit 2 have the same emitted color, the color of light emitted by the first light-emitting unit 2 is the emitted color of any light-emitting layer. When at least part of the m light-emitting layers in the first light-emitting unit 2 have different emitted colors, the color of the light emitted by the first light-emitting unit 2 is a mixture of the emitted colors of the m light-emitting layers.

Exemplarily, the light emitted by the first light-emitting layer 21, the second light-emitting layer 22 and the fifth light-emitting layer 23 in the first light-emitting unit 2 in FIG. 4 is blue, so the color of the light emitted by the first light-emitting unit 2 is blue.

The second light-emitting unit 3 includes the n light-emitting layers, and n is an integer greater than or equal to 1, that is, the second light-emitting unit 3 may emit light through a single light-emitting layer or may also emit light jointly through multiple light-emitting layers. When multiple light-emitting layers are included in the second light-emitting unit 3, its structure may be similar to that of the first light-emitting unit 2, and details are not repeated in the embodiments of the present application. Exemplarily, as shown in FIG. 7, the second light-emitting unit 3 includes a third light-emitting layer 31 and a fourth light-emitting layer 32.

The numbers m and n are not limited in the embodiments of the present application, that is, m may be greater than n, may also be less than n, or may also be equal to n.

In addition, the display panel may further include other function films except for the substrate 1, the first light-emitting units 2 and the second light-emitting units 3. Exemplarily, the display panel further includes an array layer 8 located between the substrate 1 and the first light-emitting units 2. Multiple metal wirings are disposed in the array layer 8 to form drive circuits, and thin-film transistors (TFT) are further disposed in the array layer 8. At least part of the thin-film transistors are configured to connect to the anode 92 of the first light-emitting unit 2 and the anode 92 of the second light-emitting unit 3 to control the first light-emitting unit 2 and the second light-emitting unit 3 to emit light.

In the embodiments of the present application, the effective light-emitting area of the first light-emitting unit 2 is different from the effective light-emitting area of the second light-emitting unit 3, and the effective light-emitting area is the orthographic projection area of the first light-emitting unit 2 on the substrate 1 or the orthographic projection area of the second light-emitting unit 3 on the substrate 1, or the effective light-emitting area is the sum of the orthographic projection areas of the m light-emitting layers in the first light-emitting unit 2 on the substrate 1 or the sum of the orthographic projection areas of the n light-emitting layers in the second light-emitting unit 3 on the substrate 1.

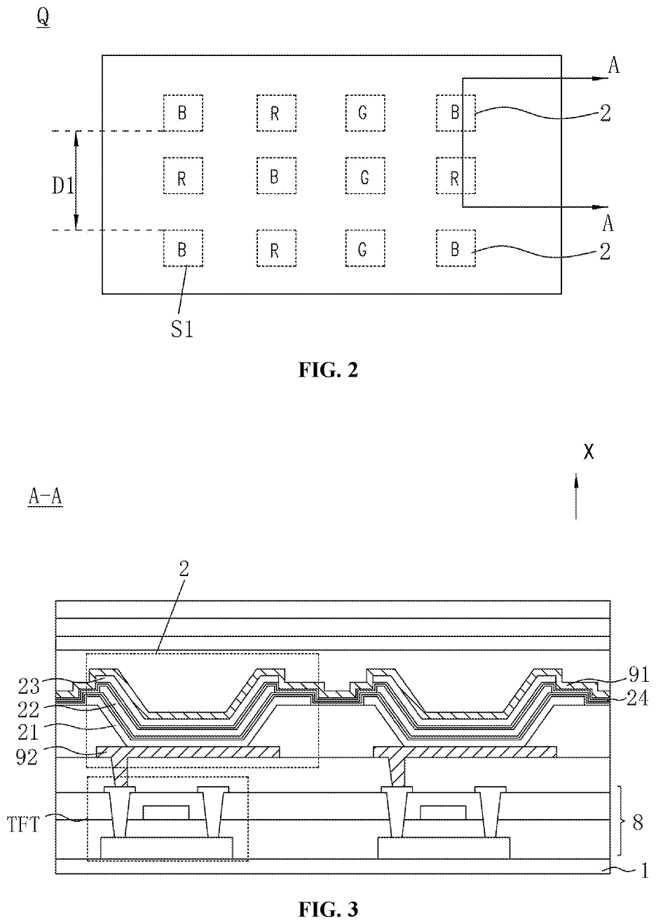

When the effective light-emitting area is the area of the orthographic projection of the first light-emitting unit 2 or the second light-emitting unit 3 on the substrate 1, as shown in FIG. 2, “the orthographic projection area of the first light-emitting unit 2 on the substrate 1” mentioned herein refers to the area S1 of an orthographic projection formed by a whole composed of the m light-emitting layers in the first light-emitting unit 2 on the substrate 1, that is, the display area of the first light-emitting unit 2. Moreover, the same holds true for “the orthographic projection area of the second light-emitting unit 3 on the substrate 1”, as shown in FIG. 5, the orthographic projection area of the second light-emitting unit 3 on the substrate 1 refers to the area S2 of an orthographic projection formed by a whole composed of the n light-emitting layers in the second light-emitting unit 2 on the substrate 1.

Therefore, the effective light-emitting area of the first light-emitting unit 2 is different from the effective light-emitting area of the second light-emitting unit 3, that is, the display area of a single first light-emitting unit 2 is different from the display area of the second light-emitting unit 3. Based on this, the display area of a single first light-emitting unit 2 and the display area of a single second light-emitting unit 3 may be adjusted so that the uniformity of the display brightness in the first display region A1 and the second display region A2 can be improved, improving the display effect.

It is to be noted that when the orthographic projections of the m light-emitting layers in the first light-emitting unit 2 on the substrate 1 coincide, the effective light-emitting area of the first light-emitting unit 2 is the orthographic projection area of a single light-emitting layer on the substrate 1, and when the orthographic projections of the m light-emitting layers in the first light-emitting unit 2 on the substrate 1 are misaligned, the effective light-emitting area of the first light-emitting unit 2 is greater than the orthographic projection area of a single light-emitting layer on the substrate 1 and is less than the sum of areas of orthographic projections of the m light-emitting layers on the substrate 1.

When the effective light-emitting area is the sum of the orthographic projection areas of the m light-emitting layers in the first light-emitting unit 2 on the substrate 1 or the sum of the orthographic projection areas of the n light-emitting layers in the second light-emitting unit 3 on the substrate 1, light-emitting regions in the m light-emitting layers form specific orthographic projections on the substrate 1 respectively. “The sum of the orthographic projection areas of the m light-emitting layers in the first light-emitting unit 2 on the substrate 1” mentioned herein refers to the sum of the orthographic projection areas corresponding to the m light-emitting layers respectively, that is, the effective light-emitting area of the first light-emitting unit 2 is determined by the number of light-emitting layers in the first light-emitting unit 2 and the orthographic projection area of each light-emitting layer on the substrate 1. Moreover, the same holds true for “the sum of the orthographic projection areas of the n light-emitting layers in the second light-emitting unit 3 on the substrate 1”.

Exemplarily, when the first light-emitting unit 2 includes the first light-emitting layer 21, the second light-emitting layer 22 and the fifth light-emitting layer 23, the orthographic projection area of the first light-emitting layer 21 on the substrate 1 is denoted as S11, the orthographic projection area of the second light-emitting layer 22 on the substrate 1 is denoted as S12, and the orthographic projection area of the fifth light-emitting layer 23 on the substrate 1 is denoted as S13. In this case, the effective light-emitting area of the first light-emitting unit 2 is S11+S12+S13.

The magnitude of the sum of the orthographic projection areas of the m light-emitting layers in the first light-emitting unit 2 on the substrate 1 and the number of light-emitting layers are usually positively correlated to the light-emitting brightness of the first light-emitting unit 2. Therefore, the effective light-emitting areas of the first light-emitting unit 2 and the second light-emitting unit 3 are adjusted so that the brightness of the single first light-emitting unit 2 and the brightness of the single second light-emitting unit 3 can be adjusted, thereby helping improve the brightness uniformity of the first display region A1 and the second display region A2, and improving the display effect.

To sum up, in the embodiments of the present application, the first light-emitting units 2 are disposed in the first display region A1, the second light-emitting units 3 are disposed in the second display region A2, and the effective light-emitting area of the first light-emitting unit 2 is different from the effective light-emitting area of the second light-emitting unit 3 so that the brightness of the first display region A1 and the brightness of the second display region A2 can be adjusted, thereby improving the brightness uniformity of different regions and improving the display effect.

In some embodiments, referring to FIGS. 4 and 7, the number m of light-emitting layers included in the first light-emitting unit 2 and the number n of light-emitting layers included in the second light-emitting unit 3 satisfy the following relationship: m>n.

The number of light-emitting layers in the first light-emitting unit 2 is greater than the number of light-emitting layers in the second light-emitting unit 3. Exemplarily, the first light-emitting unit 2 includes the first light-emitting layer 21, the second light-emitting layer 22 and the fifth light-emitting layer 23, and the second light-emitting unit 3 includes the third light-emitting layer 31 and the fourth light-emitting layer 32.

This design can enable the light-emitting brightness of the first light-emitting unit 2 to be greater than the light-emitting brightness of the second light-emitting unit 3 on the premise of the same conditions such as the display areas, and the drive current. Alternatively, the first light-emitting unit 2 may be enabled to emit light having the same intensity as the second light-emitting unit 3 when the first light-emitting unit 2 has a smaller display area than the second light-emitting unit 3 so that the brightness uniformity of the first display region A1 and the second display region A2 can be improved.

In some embodiments, the transmittance of the first display region A1 is greater than the transmittance of the second display region A2. The display panel may be provided with a photosensitive element at a position corresponding to the first display region A1 so that a full-screen display effect can be achieved.

In an electronic device such as a mobile phone or a tablet computer, the photosensitive element such as a front camera, an infrared sensor, or a proximity sensor needs to be integrated on the same side with the display panel so as to achieve specific functions such as under-screen recognition. In some schemes, a photosensitive region may be arranged in the display region AA of the preceding electronic device, the photosensitive element is disposed at the back of the photosensitive region, and light-emitting units may also be disposed in the photosensitive region for emitting light. This can achieve the full-screen display of the electronic device in a case where the photosensitive element is ensured to operate normally. However, with respect to other regions of the display region AA, the display panel needs to have a larger transmittance at the photosensitive region to enable ambient light to enter the photosensitive element.

In the embodiments of the present application, the first display region A1 is the photosensitive region while the second display region A2 is another region other than the photosensitive region in the display region AA. Since the number of light-emitting layers in the first light-emitting unit 2 in the first display region A1 is greater than the number of light-emitting layers in the second light-emitting unit 3 in the second display region A2, the first light-emitting unit 2 with a smaller display area can emit the light having the same intensity as the second light-emitting unit 3. Further, both conditions that the transmittance of the first display region A1 is greater than the transmittance of the second display region A2, and the first display region A1 and the second display region A2 have the same light-emitting intensity are satisfied by reducing the size of the first light-emitting unit 2 or the density of the first light-emitting units 2. The display uniformity can be ensured while the photosensitive function is satisfied.

In some embodiments, as shown in FIGS. 1, 3 and 6, the display panel further includes a driver chip 4, and the first display region A1 is disposed away from the driver chip 4 with respect to the first display region A1.

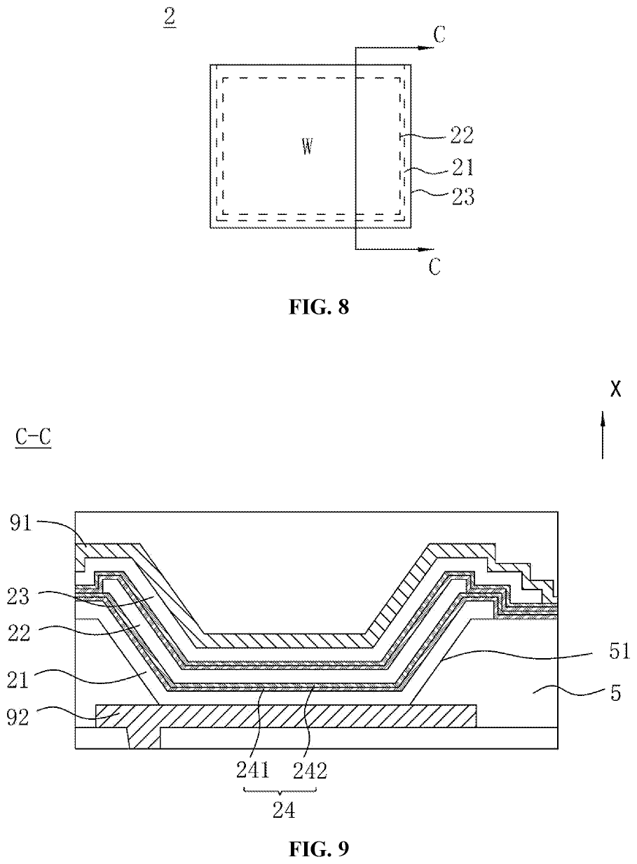

Referring to FIGS. 4 and 8, the driver chip 4 is configured to control the light emission of the first display region A1 and the light emission of the second display region A2, and is electrically connected to the first light-emitting unit 2 and the second light-emitting unit 3 through driving circuits. Generally, a light-emitting unit farther away from the driver chip 4 requires a longer driving circuit for connection, and this easily results in a larger accumulated resistance value in the driving circuit so that a drive current transmitted to the light-emitting unit is smaller.

Since the first display region A1 is disposed away from the driver chip 4 with respect to the first display region A1, a drive current received by the first light-emitting unit 2 is generally less than a drive current received by the second light-emitting unit 3. Based on this, in the embodiments of the present application, the number of light-emitting layers in the first light-emitting unit 2 is greater than that of the second light-emitting unit 3. On the premise of the same other conditions, the first light-emitting unit 2 may emit light of the same intensity as the second light-emitting unit 3 in a case of a smaller drive current so that the display uniformity can be improved.

It is to be noted that the magnitude of the drive current tends to be closely related to the service life of the display panel. When the drive current applied to the first light-emitting unit 2 is excessively large, the first light-emitting unit 2 is prone to the risks of aging and yellowing so that the display effect of the first display region A1 can be affected, and the service life of the display panel can be affected.

Moreover, in the embodiments of the present application, the first display region A1 may be the photosensitive region or may also be another region other than the photosensitive region in the display region AA. This is not limited in the embodiments of the present application. When the first display region A1 is also the photosensitive region, the display area of the first light-emitting unit 2 and the number of light-emitting layers in the first light-emitting unit 2 may be adjusted at the same time to enable the first display region A1 and the second display region A2 to have the same light-emitting brightness.

In some embodiments, as shown in FIGS. 1, 3 and 6, the minimum distance from the first display region A1 to the non-display region NA is denoted as L1, the minimum distance from the second display region A2 to the non-display region NA is denoted as L2, and L1<L2.

The minimum distance L1 from the first display region A1 to the non-display region NA is less than the minimum distance L2 from the second display region A2 to the non-display region NA, that is, the first display region A1 is closer to the non-display region NA with respect to the second display region A2. In an existing display panel, problems such as dulling easily occur at the junction between the display region AA and the non-display region NA. For this case, in the embodiments of the present application, the number of light-emitting layers in the first light-emitting unit 2 in the first display region A1 is greater than the number of light-emitting layers in the second light-emitting unit 3 so that the first display region A1 closer to the non-display region NA can have higher display brightness, thereby alleviating the problem of dulling at the junction between the display region AA and the non-display region NA and improving the display uniformity.

In some embodiments, as shown in FIGS. 2 and 5, the transmittance of the first display region A1 is greater than the transmittance of the second display region A2, the first light-emitting unit 2 and the second light-emitting unit 3 have the same emitted color, the minimum distance between two adjacent first light-emitting units 2 in the first display region A1 is denoted as D1, the minimum distance between two adjacent second light-emitting units 3 in the second display region A2 is denoted as D2, and D1−D2>0.

The magnitude of the distance between adjacent light-emitting units is determined by the pixel density and the size of each light-emitting unit in this region. When the first light-emitting units 2 in the first display region A1 and the second light-emitting units 3 in the second display region A2 have the same distribution density, the orthographic projection area of the first light-emitting unit 2 on the substrate may be set to be less than the orthographic projection area of the second light-emitting unit 3 on the substrate by controlling the size of the first light-emitting unit 2 and the size of the second light-emitting unit 3 so that the distance D1 between adjacent first light-emitting units 2 can be greater than the distance D2 between adjacent second light-emitting units 3.

When the orthographic projection area of the first light-emitting unit 2 on the substrate is the same as the orthographic projection area of the second light-emitting unit 3 on the substrate, the distribution density of the first light-emitting units 2 in the first display region A1 may be less than the distribution density of the second light-emitting units 3 in the second display region A2 by reducing the distribution density of the first light-emitting units 2 in the first display region A1 so that the distance D1 between first light-emitting units 2 can be greater than the distance D2 between adjacent second light-emitting units 3.

In the embodiments of the present application, the first display region A1 is the photosensitive region, and a region between adjacent first light-emitting units 2 is a region in the display panel, through which external light may enter to fulfill the photosensitive function. Based on this, the minimum distance between adjacent first light-emitting units 2 is greater than the minimum distance between adjacent second light-emitting units 3 so that more regions in the first display region A1 can fulfill the photosensitive function, and so that the transmittance of the first display region A1 can be greater than the transmittance of the second display region A2 in the display panel, thereby satisfying photosensitive requirements of the display panel.

In some embodiments, the orthographic projection area S1 of the first light-emitting unit 2 on the substrate 1 is less than the orthographic projection area S2 of the second light-emitting unit 3 on the substrate 1. The display area of the first light-emitting unit 2 is reduced so that the minimum distance D1 between adjacent first light-emitting units 2 can be greater than the minimum distance D2 between adjacent second light-emitting units 3 on the premise that the distribution density of the first light-emitting units 2 and the distribution density of the second light-emitting units 3 remain unchanged, thereby achieving the effect of increasing the transmittance of the display panel in the first display region A1.

In the embodiments of the present application, the sum of the orthographic projection areas of light-emitting regions of the m light-emitting layers in the first light-emitting unit 2 on the substrate 1 may be greater than the sum of the orthographic projection areas of light-emitting regions of the n light-emitting layers in the second light-emitting unit 3 on the substrate 1.

It is to be noted that the regions in the m light-emitting layers in the first light-emitting unit 2 that can emit light each have its orthographic projection on the substrate 1, and “the sum of the orthographic projection areas of the light-emitting regions of the m light-emitting layers in the first light-emitting unit 2 on the substrate 1” mentioned in the embodiments of the present application refers to the sum of the preceding m orthographic projection areas. The same holds true for “the sum of the orthographic projection areas of the light-emitting regions of the n light-emitting layers in the second light-emitting unit 3 on the substrate 1”.

As seen from the preceding, in the embodiments of the present application, though the orthographic projection area of the first light-emitting unit 2 on the substrate 1 is less than the orthographic projection area of the second light-emitting unit 3, the number of light-emitting layers in the first light-emitting unit 2 may be greater than the number of light-emitting layers in the second light-emitting unit 3. Therefore, in the first light-emitting unit 2, the number of light-emitting layers and the orthographic projection areas of the light-emitting layers on the substrate 1 may be adjusted so that the sum of the orthographic projection areas of the light-emitting regions of the m light-emitting layers in the first light-emitting unit 2 on the substrate 1 can be greater than the sum of the orthographic projection areas of the light-emitting regions of the n light-emitting layers in the second light-emitting unit 3 on the substrate 1, that is, on the premise of the same drive current, the first light-emitting unit 2 can emit light having brightness greater than or equal to that of the second light-emitting unit 3.

This design can ensure relatively high light-emitting brightness achieved in the first display region A1 while improving the transmittance of the first display region so that the light-emitting brightness of the first display region A1 and the light-emitting brightness of the second display region A2 can be unified. Moreover, in the display panel provided in the embodiments of the present application, the first display region A1 can have the same display brightness as the second display region A2 without increasing the drive current in the first display region A1 so that the risks of aging and yellowing of the first light-emitting units 2 in the first display region A1 due to an excessively large drive current can be reduced, improving the service life of the display panel.

It is to be noted that in the embodiments of the present application, the density of the first light-emitting units 2 in the first display region A1 may be the same as the second light-emitting units 3 or may be different from that of the second light-emitting units 3.

In some embodiments, the orthographic projection area S1 of the first light-emitting unit 2 on the substrate 1 is not less than the orthographic projection area S2 of the second light-emitting unit 3 on the substrate 1. The density of the first light-emitting units 2 in the first display region A1 is less than the density of the second light-emitting units 3 in the second display region A2.

From the perspective of transmittance, since the number of light-emitting layers in the first light-emitting unit 2 is greater than the number of light-emitting layers in the second light-emitting unit 3, the orthographic projection area of the first light-emitting unit 2 on the substrate 1 is greater than or equal to the orthographic projection area of the second light-emitting unit 3 on the substrate 1. To improve the transmittance of the first display region A1, the density of the first light-emitting units 2 in the first display region A1 needs to be less than the density of the second light-emitting units 3 in the second display region A2. That is, in the same display area, the number of the first light-emitting units 2 in the first display region A1 is less than the number of the second light-emitting units 3 in the second display region A2.

From the perspective of light-emitting brightness, since the density of the first light-emitting units 2 in the first display region A1 is less than the density of the second light-emitting units 3 in the second light-emitting unit 3, to ensure that the first display region A1 and the second display region A2 have the same display brightness, the light-emitting brightness of a single first light-emitting unit 2 needs to be controlled to be greater than the light-emitting brightness of a single second light-emitting unit 3. In the embodiments of the present application, the number of light-emitting layers in the first light-emitting unit 2 is controlled to be greater than the number of light-emitting units in the second light-emitting unit 3, and the display area of the first light-emitting unit 2 is controlled to be greater than the display area of the second display region A2 so that the light-emitting brightness of the first light-emitting unit 2 can be greater than the light-emitting brightness of the second light-emitting unit 3, and thus, the brightness of the first display region A1 and the brightness of the second display region A2 can be unified.

To sum up, in the embodiments of the present application, the light-emitting areas of the first light-emitting unit 2 and the second light-emitting unit 3 and the densities of the first light-emitting units 2 and the second light-emitting units 3 are controlled. This enables the first display region A1 to have higher transmittance with respect to the second display region A2 to satisfy the photosensitive requirements. Meanwhile, the light-emitting brightness of a single first light-emitting unit 2 can also be improved so that the brightness of the first display region A1 and the brightness of the second display region A2 can be unified.

In some embodiments, as shown in FIGS. 3 and 4, the display panel further includes a pixel defining layer 5 disposed on one side of the substrate 1. The pixel defining layer 5 includes a first opening 51 passing through along the thickness direction X of the substrate 1. At least part of the first light-emitting unit 2 is located inside the first opening 51. In some embodiments, at least part of the first light-emitting layer 21 is located outside the first opening 51.

When the first display region A1 is the photosensitive region, the pixel defining layer 5 may be made of a transparent material. The first opening 51 in the pixel defining layer 5 is configured to define positions of the m light-emitting layers in the first light-emitting unit 2. Exemplarily, as shown in FIG. 7, the pixel defining layer 5 further includes a second opening 52 for defining the positions of the n light-emitting layers in the second light-emitting unit 3.

A part of the first light-emitting layer 21 is located inside the first opening 51 while the other part of the first light-emitting layer 21 extends outside of the first opening 51. This design can enlarge the orthographic projection area of the first light-emitting layer 21 on the substrate 1 so that the first light-emitting layer 21 can have a larger light-emitting area. In an embodiment, the second light-emitting layer 22 is entirely located inside the first opening 51. In this case, part of the orthographic projection of the first light-emitting layer 21 on the substrate 1 does not overlap the second light-emitting layer 22, and the presence of the second light-emitting layer 22 can increase the light-emitting intensity of the part of the first light-emitting layer 21 located inside the first opening 51.

In some embodiments, as shown in FIG. 7, n is an integer greater than or equal to 2, and the n light-emitting layers in the second light-emitting unit 3 include the third light-emitting layer 31 and the fourth light-emitting layer 32. The orthographic projection of the third light-emitting layer 31 on the substrate 1 at least partially overlaps the orthographic projection of the fourth light-emitting layer 32 on the substrate 1. The orthographic projection area of the third light-emitting layer 31 on the substrate 1 is greater than the orthographic projection area of the fourth light-emitting layer 32 on the substrate 1.

In the embodiments of the present application, multiple light-emitting layers are provided in the second light-emitting unit 3. A second connecting layer 33 may also be disposed between adjacent light-emitting layers in the second light-emitting unit 3, and the adjacent light-emitting layers emit light in series through the second connecting layer 33. The n light-emitting layers include the third light-emitting layer 31 and the fourth light-emitting layer 32. “The orthographic projection of the third light-emitting layer 31 on the substrate 1 at least partially overlaps the orthographic projection of the fourth light-emitting layer 32 on the substrate 1” mentioned in the embodiments of the present application refers to the following: The third light-emitting layer 31 has a third orthographic projection on the substrate 1, the fourth light-emitting layer 32 has a fourth orthographic projection on the substrate 1, and an overlapping region exists between the third orthographic projection and the fourth orthographic projection. When third light-emitting units 6 are configured to display, the third light-emitting layer 31 and the fourth light-emitting layer 32 emit light jointly and emit stronger light at a position corresponding to the overlapping region, thereby improving the light-emitting brightness.

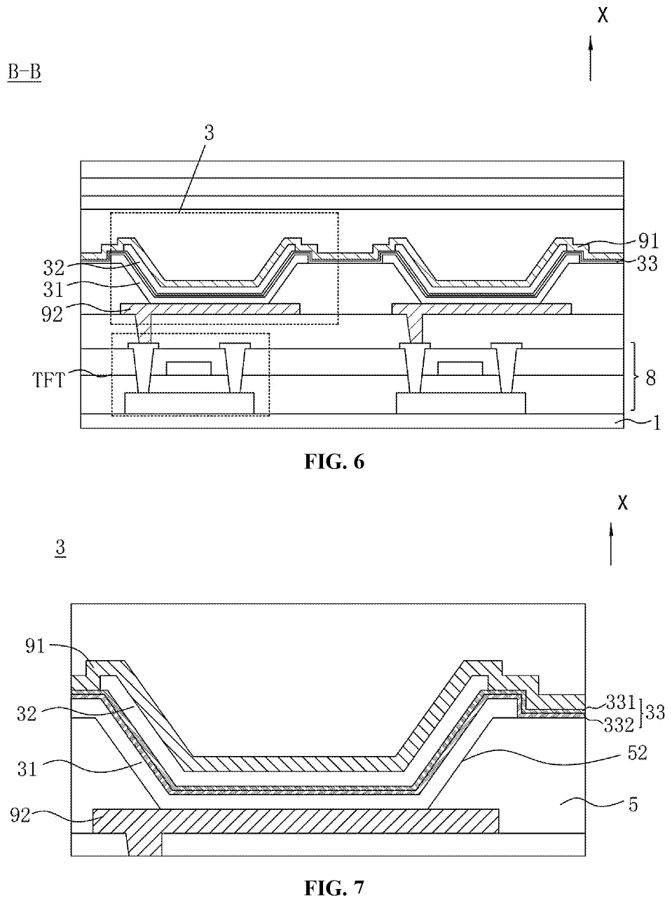

For the first light-emitting unit 2 and the second light-emitting unit 3, as shown in FIGS. 5 and 6, the number m of the light-emitting layers in the first light-emitting unit 2 may be greater than the number n of the light-emitting layers in the second light-emitting unit 3. Alternatively, m may also be set to be less than n, or even m and n are set to be the same. This is not limited in the embodiments of the present application.

To enable the first display region A1 and the second display region A2 to have the same display brightness, the first light-emitting unit 2 and the second light-emitting unit 3 need to be adjusted. In addition to simultaneously adjusting all light-emitting layers in the first light-emitting unit 2 or all light-emitting layers in the second light-emitting unit 3, some certain light-emitting layers in the second light-emitting unit 3 may also be adjusted.

In the embodiments of the present application, the size of the fourth light-emitting layer 32 is reduced so that the orthographic projection area of the fourth light-emitting layer 32 on the substrate 1 can be less than the orthographic projection area of the third light-emitting layer 31 on the substrate 1, thereby reducing the light-emitting brightness of the second light-emitting unit 3 to a certain extent, such that the brightness of the first display region A1 and the brightness of the second display region A2 can be unified. Similarly, the sizes of part of the m light-emitting layers in the first light-emitting unit 2 may also be enlarged so that the light-emitting brightness of the first light-emitting unit 2 can be increased, thereby improving the brightness uniformity of the first display region A1 and the second display region A2.

It is to be noted that the n light-emitting layers in the second light-emitting unit 3 may have the same emitted color or different emitted colors. This is not limited in the embodiments of the present application. When at least part of the n light-emitting layers in the second light-emitting unit 3 have different emitted colors, the color of light emitted by the second light-emitting unit 3 is a mixture of the emitted colors of the n light-emitting layers.

In some embodiments, as shown in FIGS. 6 and 7, the fourth light-emitting layer 32 is located on one side of the third light-emitting layer 31 facing away from the substrate 1.

With respect to the third light-emitting layer 31, the fourth light-emitting layer 32 is relatively closer to the side of the light-emitting surface of the display panel, so the number of films through which light emitted by the fourth light-emitting layer 32 needs to pass is smaller, that is, the light loss is smaller, and the size of the fourth light-emitting layer 32 does not need to be excessively large. Therefore, in the embodiments of the present application, the size of the fourth light-emitting layer 32 is reduced moderately so that the orthographic projection of the fourth light-emitting layer 32 on the substrate 1 can be less than the size of the orthographic projection of the third light-emitting layer 31 on the substrate 1.

In some embodiments, referring to FIGS. 1, 8 and 9, the transmittance of the first display region A1 is greater than the transmittance of the second display region A2, and the m light-emitting layers in the first light-emitting unit 2 further include the fifth light-emitting layer 23. For at least part of the first light-emitting units 2, the emitted color of the first light-emitting layer 21 is red, the emitted color of the second light-emitting layer 22 is green, and the emitted color of the fifth light-emitting layer 23 is blue. The orthographic projection area of the fifth light-emitting layer 23 on the substrate 1 is greater than the orthographic projection area of the first light-emitting layer 21 on the substrate 1, and the orthographic projection area of the first light-emitting layer 21 on the substrate 1 is greater than the orthographic projection area of the second light-emitting layer 22 on the substrate 1.

The first display region A1 is the photosensitive region. The first light-emitting unit 2 in the first display region A1 includes multiple light-emitting layers that emit red light, green light and blue light respectively. Under a mixed light-emitting action of the multiple light-emitting layers, the first light-emitting unit 2 may emit white light. In the existing art, if a specific light-emitting unit is to be able to emit white light, the light-emitting unit needs to be disposed as a white sub-pixel. In the embodiments of the present application, no white light-emitting layer needs to be disposed in the first light-emitting unit 2, and only the common red, blue and green light-emitting layers need to be stacked so that the white light-emitting effect can be achieved by mixing the red, blue and green light-emitting layers to emit light.

Moreover, in the embodiments of the present application, the sizes of the first light-emitting layer 21, the second light-emitting layer 22 and the fifth light-emitting layer 23 are adjusted so that the chromaticity of the white light emitted by the first light-emitting unit 2 can be adjusted. Compared with the existing art, a more accurate display effect can be provided, and the restoration degree of a display picture can be improved.

It is to be noted that not only the light-emitting units emitting red light, green light, blue light and white light but also other light-emitting units having multiple colors may be included in the first display region A1. Exemplarily, the display panel may include a light-emitting unit emitting yellow light, and multiple light-emitting layers emitting red light and green light are included in the light-emitting unit emitting yellow light.

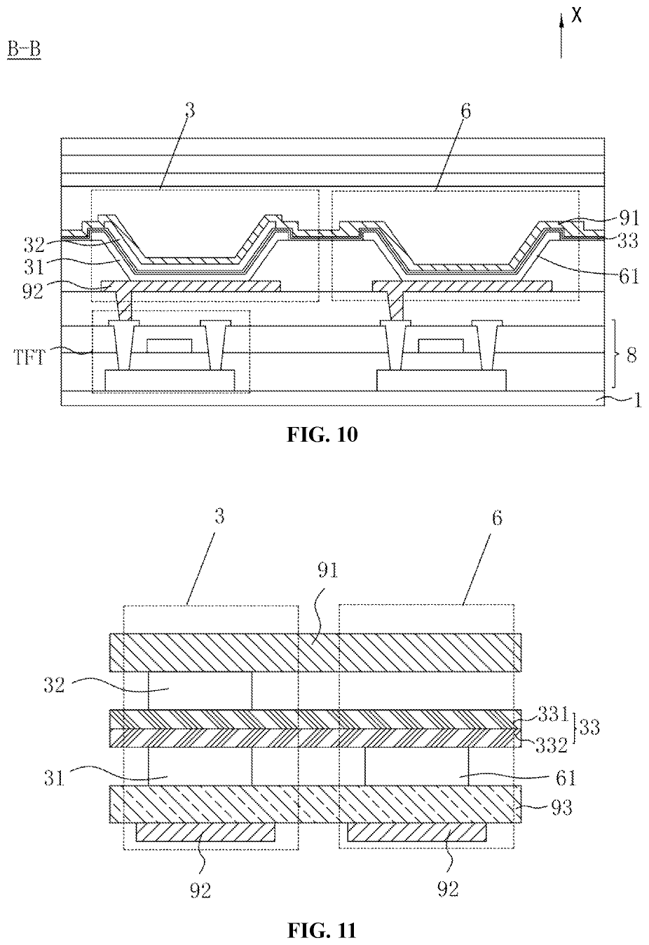

In some embodiments, referring to FIGS. 1, 10 and 11, the display panel further includes third light-emitting units 6 located in the second display region A2. A third light-emitting unit 6 includes i light-emitting layers, and i is an integer greater than or equal to 1. i≤n. In the embodiments of the present application, the second light-emitting unit 3 has the same structure as FIG. 7.

The second light-emitting units 3 and the third light-emitting units 6 are located in the second display region A2. A light-emitting unit having the same emitted color as the third light-emitting unit 6 is also present in the first display region A1. The third light-emitting unit 6 has a structure similar to the second light-emitting unit 3, but the difference lies in that the number of light-emitting layers in the third light-emitting layer 6 is less than the number of light-emitting layers in the second light-emitting unit 3. Exemplarily, the second light-emitting unit 3 includes the third light-emitting layer 31 and the fourth light-emitting layer 32, the third light-emitting unit 6 includes a sixth light-emitting layer 61, and films such a hole transport layer 93 are disposed between the anode 92 and the third light-emitting layer 31.

For light-emitting units having different emitted colors, the light-emitting units have different service lives, and some light-emitting units are relatively prone to aging and yellowing so that a color cast can occur. Some light-emitting units have relatively long service lives, so it is rather difficult to cause a color cast. For different features of different types of light-emitting units, in the embodiments of the present application, the number of light-emitting layers in the third light-emitting unit 6 in the second display region A2 can be less than that in other light-emitting units so that light-emitting units having the same emitted color in the first display region A1 can be indirectly compensated for.

It is to be noted that in the embodiments of the present application, the number i of the light-emitting layers in the third light-emitting unit 6 may be less than the number m of the light-emitting layers in the first light-emitting unit 2, or i may be equal to m or even greater than m. This is not limited in the embodiments of the present application.

In some embodiments, the third light-emitting units 6 are configured to emit blue light. With respect to light-emitting units having other colors, the blue light-emitting unit generally has a relatively low service life, so it is prone to a color cast. Exemplarily, when the first display region A1 is the photosensitive region, the number of light-emitting layers in the blue light-emitting unit in the second display region A2 is reduced so that the uniformity of blue light emitted by the first display region A1 and the second display region A2 can be ensured, and blue light-emitting units in the photosensitive region can be compensated for.

In some embodiments, as shown in FIG. 4, the second light-emitting layer 22 is located on one side of the first light-emitting layer 21 facing away from the substrate 1, and the orthographic projection of the first light-emitting layer 21 on the substrate 1 covers the second light-emitting layer 22.

As seen from the preceding, to improve the brightness uniformity of the first display region A1 and the second display region A2, multiple light-emitting layers are provided in the first light-emitting unit 2. That is, the second light-emitting layer 22 even more light-emitting layers are additionally provided based on the original first light-emitting layer 21.

To prevent the additionally added light-emitting layers from affecting the transmittance of the first display region A1, in the embodiments of the present application, the orthographic projection of the first light-emitting layer 21 on the substrate 1 covers the second light-emitting layer 22, that is, the orthographic projection of the second light-emitting layer 22 on the substrate 1 is located inside the first light-emitting layer 21. This design can reduce the influence on the transmittance of the first display area A1 while increasing the light-emitting brightness of the first light-emitting unit 2.

In some embodiments, as shown in FIGS. 4 and 7, the first light-emitting unit 2 further includes the first connecting layer 24 disposed between adjacent light-emitting layers, and the second light-emitting unit 3 further includes the second connecting layer 33 disposed between adjacent light-emitting layers. The first connecting layer 24 includes a first doping layer 241 and a second doping layer 242 that are stacked, and the first doping layer 241 and the second doping layer 242 are configured to transmit holes or electrons to two adjacent light-emitting layers in the first light-emitting unit 2, respectively.

The second connecting layer 33 includes a third doping layer 331 and a fourth doping layer 332 that are stacked, and the third doping layer 331 and the fourth doping layer 332 are configured to transmit holes or electrons to two adjacent light-emitting layers in the second light-emitting unit 3, respectively.

The first connecting layer 24 is configured to connect adjacent light-emitting layers of the first light-emitting unit 2 in series. The second connecting layer 33 is configured to connect adjacent light-emitting layers of the second light-emitting unit 3 in series. The first connecting layer 24 includes the first doping layer 241 and the second doping layer 242. The first doping layer 241 and the second doping layer 242 are a p-type doping layer and an n-type doping layer respectively. The p-type doping layer includes a material such as HAT-CN, TCNQ, or NDP-9, or a combination thereof to facilitate the transmission of holes. The n-type doping layer includes a material such as an alkali metal, an alkaline earth metal, a lanthanide metal, or a combination thereof to facilitate the transmission of electrons.

The second connecting layer 33 has a structure similar to the first connecting layer 24, and details are not repeated in the embodiments of the present application.

It is to be noted that the first connecting layer 24 not only includes the first doping layer 241 and the second doping layer 242 but may also include films such as the hole transport layer and the electron transport layer (not shown in the figure). This is not limited in the embodiments of the present application, and the same holds true for the second connecting layer 33.

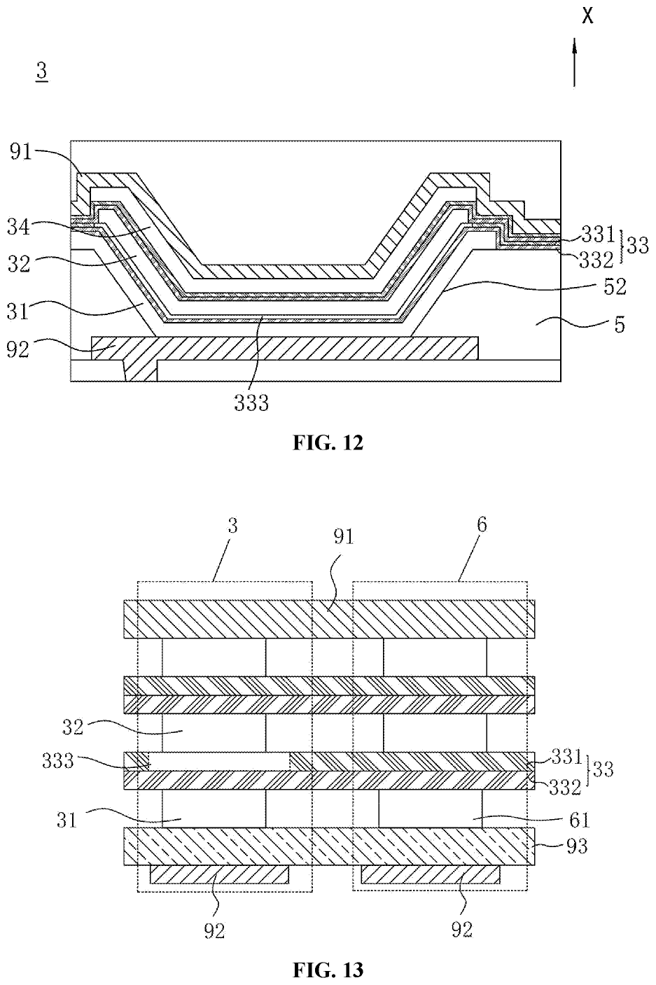

In some embodiments, as shown in FIGS. 12 and 13, at least one of the third doping layer 331 and the fourth doping layer 332 is provided with a through hole 333 passing through along the thickness direction X in at least part of the second connecting layer 33, and the orthographic projection of the through hole 333 on the substrate at least partially overlaps orthographic projections of adjacent light-emitting layers.

The third doping layer 331 and the fourth doping layer 332 are configured to transmit holes or electrons to the two adjacent light-emitting layers in the second light-emitting unit 3 respectively. When one of the third doping layer 331 and the fourth doping layer 332 has the through hole 333, the light-emitting layers adjacent to the through hole 333 have reduced light-emitting brightness and even cannot emit light.

Exemplarily, as shown in FIG. 12, the second light-emitting unit 3 includes the third light-emitting layer 31, the fourth light-emitting layer 32 and a seventh light-emitting layer 34, and the through hole 333 is located on the third doping layer 331 in the second connecting layer 33 between the third light-emitting layer 31 and the fourth light-emitting layer 32. Due to the presence of the through hole 333, the number of holes transmitted to the fourth light-emitting layer 32 is reduced so that the fourth light-emitting layer 34 can have reduced light-emitting brightness and cannot even emit light.

When the through hole 333 is disposed on the third doping layer 331, an overlapping region is present between the orthographic projection of the through hole 333 on the substrate 1 and the orthographic projection of the fourth light-emitting layer 32 on the substrate 1. Part of the fourth light-emitting layer 32 corresponding to the overlapping region cannot perform hole transmission with the third doping layer 331, so the number of holes transmitted by the fourth light-emitting layer 32 and the third doping layer 331 is reduced so that the light-emitting brightness of the fourth light-emitting layer 32 can be reduced. In an embodiment, the orthographic projection of the through hole 333 on the substrate covers the orthographic projection of the fourth light-emitting layer 32 on the substrate so that the fourth light-emitting layer 32 cannot emit light.

It is to be noted that the third doping layer 331 and the fourth doping layer 332 in the second connecting layer 33 are common films, and multiple second light-emitting units 3 may share the same third doping layer 331 and fourth doping layer 332. When the through hole 333 is present in the third doping layer 331, the holes may still diffuse and propagate in other regions of the third doping layer 331 other than the through hole 333, so the presence of the through hole 333 only affects a specific light-emitting layer in a specific second light-emitting unit 3, and neither the other light-emitting layers in the second light-emitting unit 3 nor the other second light-emitting units 3 are affected.

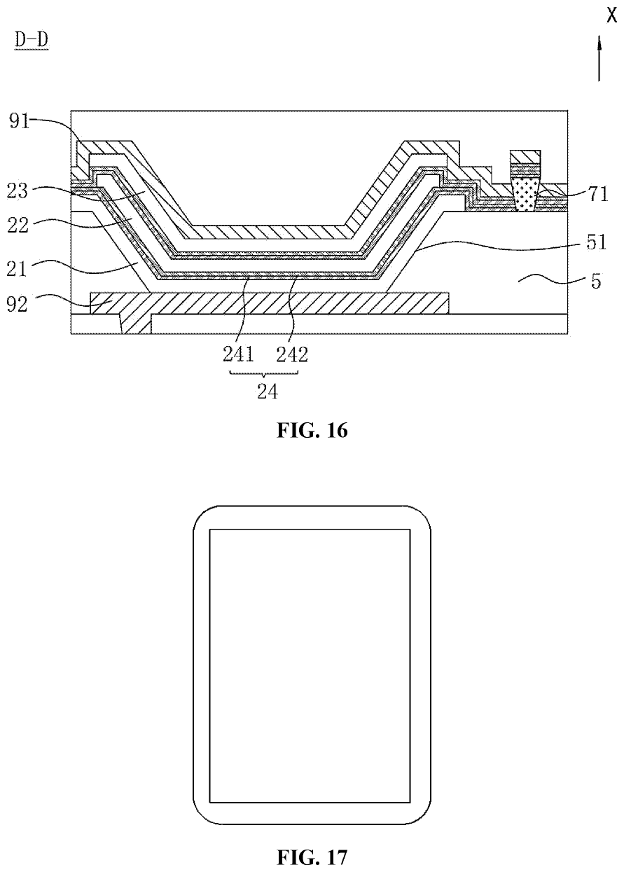

In some embodiments, referring to FIGS. 1 and 14 to 16, the display panel further includes a first barrier column 71 disposed on an outer peripheral side of the first light-emitting unit 2 and a second barrier column 72 disposed on an outer peripheral side of the second light-emitting unit 3.

The first barrier column 71 and the second barrier column 72 support and protect the first light-emitting unit 2 and the second light-emitting unit 3 respectively. In an embodiment, multiple first barrier columns 71 and multiple second barrier columns 72 are provided. The multiple first barrier columns 71 surround the outer peripheral side of the first light-emitting unit 2, and the multiple second barrier columns 72 surround the outer peripheral side of the second light-emitting unit 3. In some embodiments, the number of the first barrier columns 71 is less than the number of the second barrier columns 72.

Generally, the presence of the first barrier column 71 and the second barrier column 72 increases the cathode resistance values of the light-emitting units, and the larger the number of first barrier columns 71 and second barrier columns 72, the greater their influences on the cathode resistances. Based on this, in the embodiments of the present application, the number of the first barrier columns 71 is less than the number of the second barrier columns 72 so that the cathode resistance corresponding to the first light-emitting unit 2 can be smaller than the cathode resistance corresponding to the second light-emitting unit 3, enabling the light-emitting brightness of the first light-emitting unit 2 to be stronger and thereby improving the brightness uniformity of the first display region A1 and the second display region A2.

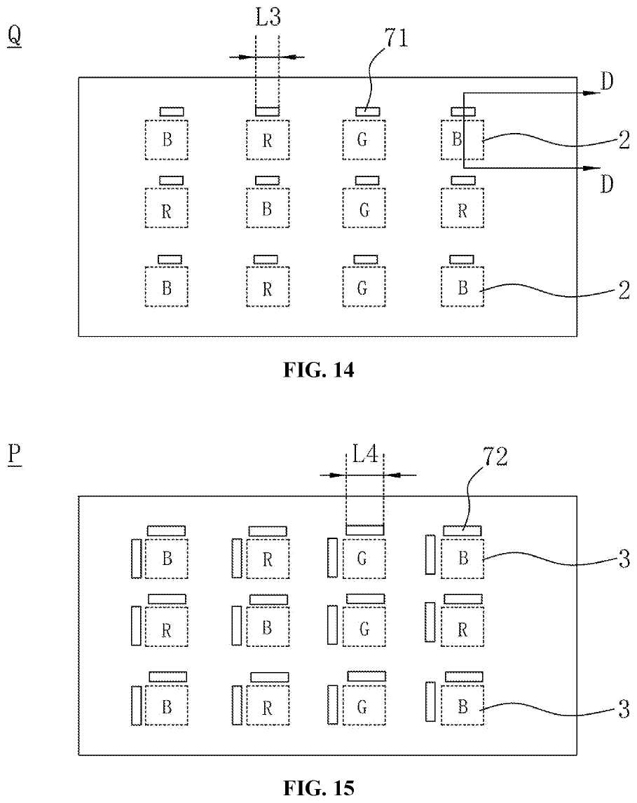

Exemplarily, as shown in FIG. 14, one first barrier column 71 is disposed outside a single first light-emitting unit 2, and the first barrier column 71 may be disposed near any edge of the first light-emitting unit 2. As shown in FIG. 15, two second barrier columns 72 are disposed outside a single second light-emitting unit 3, and the two second barrier columns 72 are distributed on two adjacent sides of the second light-emitting unit 3. In some other embodiments, the two second barrier columns 72 may also be symmetrically distributed on two sides of the second light-emitting unit 3, or three or more second barrier columns 72 are provided. This is not limited in the embodiments of the present application.

In some embodiments, the orthographic projection length L3 of the first barrier column 71 on the substrate is less than the orthographic projection length L4 of the second barrier column 72 on the substrate.

As seen from the preceding, the presence of the first barrier column 71 and the second barrier column 72 increases the cathode resistance values of the light-emitting units. Further, if the orthographic projection lengths of the first barrier column 71 and the second barrier column 72 are larger, their influences on the cathode resistances are also larger, so the light-emitting brightness is lower under the same conditions.

Therefore, in the embodiments of the present application, the orthographic projection length L3 of the first barrier column 71 on the substrate is less than the orthographic projection length L4 of the second barrier column 72 on the substrate so that the cathode resistance corresponding to the first light-emitting unit 2 can be smaller than the cathode resistance corresponding to the second light-emitting unit 3, enabling the light-emitting brightness of the first light-emitting unit 2 to be stronger and thereby improving the brightness uniformity of the first display region A1 and the second display region A2.

In addition, the orthographic projection width of the first barrier column 71 on the substrate may also be less than the orthographic projection width of the second barrier column 72 on the substrate so that the orthographic projection area of the first barrier column 71 on the substrate can be less than the orthographic projection area of the second barrier column 72 on the substrate, reducing the influence of the first barrier column 71 on the cathode resistance.

In some embodiments, at least part of the m light-emitting layers in the first light-emitting unit 2 are in the same layer as at least part of the n light-emitting layers in the second light-emitting unit 3.

The first light-emitting unit 2 and the second light-emitting unit 3 may be each a structure having multiple light-emitting layers. The positions of the multiple light-emitting layers correspond to the position of the first light-emitting unit 2 or the second light-emitting unit 3. To improve the preparation efficiency of the display panel, the embodiments of the present application set at least part of the m light-emitting layers in the first light-emitting unit 2 to be in the same layer as at least part of the n light-emitting layers in the second light-emitting unit 3 so that the at least part of the m light-emitting layers in the first light-emitting unit 2 and the at least part of the n light-emitting layers in the second light-emitting unit 3 can be formed in the same evaporation process, simplifying the preparation process and improving the preparation efficiency.

In a second aspect, referring to FIG. 17, an embodiment of the present application provides a display device. The display device includes the display panel in any preceding embodiment.

It is to be noted that the display device provided in the embodiment of the present application has the beneficial effects of the display panel in any preceding embodiment. For the beneficial effects of the display device, references can be made to the preceding descriptions of the display panel, and details are not repeated in the embodiment of the present application.

Although the embodiments disclosed by the present application are as described in the preceding, the content thereof is merely embodiments for facilitating the understanding of the present application and is not intended to limit the present application. Any person skilled in the art to which the present application pertains may make any modifications and variations in the implementation forms and details without departing from the spirit and scope disclosed by the present application, but the protection scope of the present application is still subject to the scope defined by the appended claims.

The preceding are merely embodiments of the present application. For convenience and brevity of the description, it will be apparent to those skilled in the art that substitutions of other connection manners described in the preceding can refer to the corresponding processes in the preceding method embodiments, and details are not repeated herein. It is to be understood that the protection scope of the present application is not limited thereto, and that it is easy for those skilled in the art to conceive equivalent modifications or substitutions within the technical scope disclosed in the present application. These modifications or substitutions are within the protection scope of the present application.

1. A display panel, comprising: a first display region, a second display region, a substrate;
first light-emitting units disposed on one side of the substrate in the first display region, wherein a first light-emitting unit of the first light-emitting units comprises m light-emitting layers, m is an integer greater than or equal to 2, the m light-emitting layers comprise a first light-emitting layer and a second light-emitting layer, and an orthographic projection of the first light-emitting layer on the substrate at least partially overlaps an orthographic projection of the second light-emitting layer on the substrate; and
second light-emitting units disposed on one side of the substrate in the second display region, wherein a second light-emitting unit of the second light-emitting units comprises n light-emitting layers, and n is an integer greater than or equal to 1;
wherein an effective light-emitting area of the first light-emitting unit is different from an effective light-emitting area of the second light-emitting unit,
wherein the effective light-emitting area of the first light-emitting unit is an orthographic projection area of the first light-emitting unit on the substrate, and the effective light-emitting area of the second light-emitting unit is an orthographic projection area of the second light-emitting unit on the substrate; or the effective light-emitting area of the first light-emitting unit is a sum of orthographic projection areas of the m light-emitting layers in the first light-emitting unit on the substrate, and the effective light-emitting area of the second light-emitting unit is a sum of orthographic projection areas of the n light-emitting layers in the second light-emitting unit on the substrate.

2. The display panel according to claim 1, wherein the number m of light-emitting layers comprised in the first light-emitting unit and the number n of light-emitting layers comprised in the second light-emitting unit satisfy a relationship: m>n.

3. The display panel according to claim 2, wherein a transmittance of the first display region is greater than a transmittance of the second display region; or
the display panel further comprises a driver chip, and the first display region is disposed away from the driver chip with respect to the second display region; or
a minimum distance from the first display region to a non-display region of the display panel is denoted as L1, and a minimum distance from the second display region to the non-display region is denoted as L2, wherein L1<L2.

4. The display panel according to claim 2, wherein a transmittance of the first display region is greater than a transmittance of the second display region, the first light-emitting unit and the second light-emitting unit have a same emitted color, a minimum distance between two adjacent ones of the first light-emitting units in the first display region is denoted as D1, and a minimum distance between two adjacent ones of the second light-emitting units in the second display region is denoted as D2,
wherein D1−D2>0.

5. The display panel according to claim 2, wherein the orthographic projection area of the first light-emitting unit on the substrate is less than the orthographic projection area of the second light-emitting unit on the substrate.

6. The display panel according to claim 5, wherein a sum of orthographic projection areas of light-emitting regions of the m light-emitting layers in the first light-emitting unit on the substrate is greater than a sum of orthographic projection areas of light-emitting regions of the n light-emitting layers in the second light-emitting unit on the substrate.

7. The display panel according to claim 2, wherein the orthographic projection area of the first light-emitting unit on the substrate is not less than the orthographic projection area of the second light-emitting unit on the substrate; and
a density of the first light-emitting units in the first display region is less than a density of the second light-emitting units in the second display region.

8. The display region according to claim 1, further comprising a pixel defining layer disposed on one side of the substrate, wherein the pixel defining layer comprises a first opening passing through along a thickness direction of the substrate, and at least part of the first light-emitting unit is located inside the first opening,
wherein at least part of the first light-emitting layer is located outside the first opening.

9. The display panel according to claim 1, wherein n is an integer greater than or equal to 2, the n light-emitting layers comprise a third light-emitting layer and a fourth light-emitting layer, an orthographic projection of the third light-emitting layer on the substrate at least partially overlaps an orthographic projection of the fourth light-emitting layer on the substrate, and an orthographic projection area of the third light-emitting layer on the substrate is greater than an orthographic projection area of the fourth light-emitting layer on the substrate.

10. The display panel according to claim 9, wherein the fourth light-emitting layer is located on one side of the third light-emitting layer facing away from the substrate.

11. The display panel according to claim 1, wherein a transmittance of the first display region is greater than a transmittance of the second display region, the m light-emitting layers further comprise a fifth light-emitting layer, and
for at least part of the first light-emitting units, an emitted color of first light-emitting layers is red, an emitted color of second light-emitting layers is green, and an emitted color of fifth light-emitting layers is blue,
wherein an orthographic projection area of the fifth light-emitting layer on the substrate is greater than an orthographic projection area of the first light-emitting layer on the substrate, and the orthographic projection area of the first light-emitting layer on the substrate is greater than an orthographic projection area of the second light-emitting layer on the substrate.

12. The display panel according to claim 1, further comprising third light-emitting units located in the second display region, wherein a third light-emitting unit of the third light-emitting units comprises i light-emitting layers, and i is an integer greater than or equal to 1, wherein i≤n.

13. The display panel according to claim 12, wherein the third light-emitting units are configured to emit blue light.

14. The display panel according to claim 1, wherein the second light-emitting layer is located on one side of the first light-emitting layer facing away from the substrate, and the orthographic projection of the first light-emitting layer on the substrate covers the second light-emitting layer.

15. The display panel according to claim 1, wherein the first light-emitting unit further comprises a first connecting layer disposed between adjacent light-emitting layers among the m light-emitting layers, and the second light-emitting unit further comprises a second connecting layer disposed between adjacent light-emitting layers among the n light-emitting layers;
the first connecting layer comprises a first doping layer and a second doping layer that are stacked, and the first doping layer and the second doping layer are configured to transmit a hole or an electron to two adjacent light-emitting layers among the m light-emitting layers in the first light-emitting unit respectively; and
the second connecting layer comprises a third doping layer and a fourth doping layer that are stacked, and the third doping layer and the fourth doping layer are configured to transmit a hole or an electron to two adjacent light-emitting layers among the n light-emitting layers in the second light-emitting unit respectively.

16. The display panel according to claim 15, wherein at least part of at least one of the third doping layer or the fourth doping layer in the second connecting layer is provided with a through hole passing through along a thickness direction of the substrate, and an orthographic projection of the through hole on the substrate at least partially overlaps orthographic projections of the two adjacent light-emitting layers on the substrate.

17. The display panel according to claim 1, further comprising a first barrier column disposed on an outer peripheral side of the first light-emitting unit and a second barrier column disposed on an outer peripheral side of the second light-emitting unit.

18. The display panel according to claim 17, wherein a number of first barrier columns is less than a number of second barrier columns; and/or
an orthographic projection length of the first barrier column on the substrate is less than an orthographic projection length of the second barrier column on the substrate.

19. The display panel according to claim 1, wherein at least part of the m light-emitting layers in the first light-emitting unit and at least part of the n light-emitting layers in the second light-emitting unit are disposed in a same layer.

20. A display device, comprising a display panel, wherein the display panel comprises a first display region, a second display region, a substrate, first light-emitting units, and second light-emitting units; wherein the first light-emitting units are disposed on one side of the substrate in the first display region, a first light-emitting unit of the first light-emitting units comprises m light-emitting layers, m is an integer greater than or equal to 2, the m light-emitting layers comprise a first light-emitting layer and a second light-emitting layer, and an orthographic projection of the first light-emitting layer on the substrate at least partially overlaps an orthographic projection of the second light-emitting layer on the substrate; and the second light-emitting units are disposed on one side of the substrate in the second display region, a second light-emitting unit of the second light-emitting units comprises n light-emitting layers, and n is an integer greater than or equal to 1;
wherein an effective light-emitting area of the first light-emitting unit is different from an effective light-emitting area of the second light-emitting unit,
wherein the effective light-emitting area of the first light-emitting unit is an orthographic projection area of the first light-emitting unit on the substrate, and the effective light-emitting area of the second light-emitting unit is an orthographic projection area of the second light-emitting unit on the substrate; or the effective light-emitting area of the first light-emitting unit is a sum of orthographic projection areas of the m light-emitting layers in the first light-emitting unit on the substrate, and the effective light-emitting area of the second light-emitting unit is a sum of orthographic projection areas of the n light-emitting layers in the second light-emitting unit on the substrate.
